(19) United States
(12) Patent Application Publication
(10) Pub. No.: US 2007/0242425 A1
(43) Pub. Date: Oct. 18, 2007

(54) PERSONAL COMPUTER

(76) Inventors: Jakob Roelof Van Den Berg, Driebergen (NL); Joseph Johannes Petrus Maria Muller, 's-Hertogenbosch (NL)

Correspondence Address: PEACOCK MYERS, P.C., 201 THIRD STREET, N.W., SUITE 1340, ALBUQUERQUE, NM, 87102, US

(21) Appl. No.: 11/675,363

(22) Filed: Feb. 15, 2007

Related U.S. Application Data
(63) Continuation-in-part of application No. PCT/NL05/00592, filed on Aug. 17, 2005.

(30) Foreign Application Priority Data
Aug. 17, 2004 (NL) NL 1026846

(51) Int. Cl. H05K 7/20

(52) U.S. Cl. 361/687

(57) ABSTRACT

A personal computer comprising a housing, and placed in the housing a motherboard that is at least provided with one central processor unit, which computer is provided with input and output connections for peripheral equipment such as VDU, keyboard and mouse. A heat sink is provided whose capacity is geared to the heat generation of the central processor unit, wherein the housing is embodied without fan and without an accessory fan drive, wherein the heat sink is an integral part of the housing, and the motherboard is mounted in the housing in such manner that the central processor unit is stably positioned against the heat sink.

### CROSS-REFERENCE TO RELATED APPLICATIONS

This application is a continuation-in-part application of International Ser. No. PCT/NL2005/000592, entitled “Personal Computer”, filed on Aug. 17, 2005, and the specification, drawings and claims thereof are incorporated herein by reference.

This application, Ser. No. PCT/NL2005/000564, claims priority to and the benefit of the filing of Netherlands Patent Application Ser. No. 1026846, entitled “Personal Computer”, filed on Aug. 17, 2004, and the specification, drawings and claims thereof are incorporated herein by reference.

### STATEMENT REGARDING FEDERALLY SPONSORED RESEARCH OR DEVELOPMENT

Not Applicable.

### INCORPORATION BY REFERENCE OF MATERIAL SUBMITTED ON A COMPACT DISC

Not Applicable.

### COPYRIGHTED MATERIAL

Not Applicable.

### BACKGROUND OF THE INVENTION

1. Description of Related Art

The invention relates to a personal computer comprising a housing, and placed in the housing a motherboard that is at least provided with one central processor unit, which computer is provided with input and output connections for peripheral equipment such as VDU, keyboard and mouse, and which is provided with a heat sink whose capacity is geared to the heat generation of the central processor unit, wherein the housing is coupled with the heat sink, and is embodied without fan and without an accessory fan drive. Such a personal computer is known from U.S. Pat. No. 5,570,270.

The known personal computer or PC has the drawback that, with respect to its construction, it is designed to operate in a challenging environment as far as temperature and pollution are concerned, the price playing a secondary part.

2. Field of the Invention (Technical Field)

It is the object of the invention to provide a personal computer that is quiet and, if desired, can very suitably be employed in a polluted environment without adverse consequences for the operational components of the PC, while its production costs are nonetheless low.

It also is an object of the invention to provide such a personal computer that is very suitable for mobile use. To this end, the personal computer according to the invention is in a first aspect characterized in that the heat sink is an integral part of the housing, and in that the motherboard is mounted in the housing in such a manner that the central processor unit is stably positioned against the heat sink.

### BRIEF SUMMARY OF THE INVENTION

The invention is based on the insight that in this manner it is possible to embody the personal computer without fan and thereby combat pollution of the PC's interior as well. In addition, mounting the motherboard on the heat sink greatly reduces the mechanical and thermal load of this motherboard and in particular, of the central processor unit mounted on the motherboard. This is very advantageous when using the computer in mobile applications.

In order to further the stability with which the central processor unit is mounted against the heat sink, it is advantageous that the motherboard, while the same is provided with the central processor unit, be mounted on the heat sink using a frame in such a manner that the central processor unit is positioned between the motherboard, the heat sink and the frame's legs surrounding the central processor unit. The frame thus imparts stability and rigidity on the construction within which the central processor unit is accommodated.

To improve the contact for the heat transfer between the central processor unit and the heat sink, it is also advantageous that a contact paste be applied between the heat sink and the central processor unit.

A further preferred embodiment of the personal computer according to the invention is characterized in that the central processor unit is of the kind that has an electricity saving function, and that the electricity saving function is at least partly deactivated. Such a processor unit is, for example, the processor unit sold by Intel Corp. under the name of Centrino®. The manner in which the electricity saving function has to be deactivated is well known to the person skilled in the art and requires no further explanation.

Still a further preferred embodiment of the personal computer according to the invention is characterized in that the input and output connections and the respective software interfaces are limited to general peripheral equipment applications with USB, 1394 (firewire) and LAN.

It should be noted that the above-mentioned preferred embodiments can also effectively be applied in combination. Designing the personal computer according to the invention with a low power requirement also greatly reduces the requirements regarding heat dissipation so that the housing can be embodied without fan and accessory fan drive. Moreover, the omission of the fan drive further reduces the power requirement of the integral personal computer, and also reduces the generation of heat, so that in this sense a synergistic plus effect is achieved. An additional important advantage of this measure is that the personal computer according to the invention produces less noise and suffers less pollution.

The inventiveness of the personal computer proposed by the applicant is illustrated by, among other things, the long lapse of time since the introduction of the personal computer according to the prior art, and the present proposal to embody the computer in the manner specified in claim 1 and the sub-claims.

With regard to the practicality of the personal computer in a polluted environment, it is desirable for the housing to have no ventilation openings at all.

The personal computer according to the invention may be provided in the usual manner with a built-in power supply unit. However, it may be advantageous to embody the computer according to the invention such that a connection for an external power supply is provided and that there is no power supply unit inside the housing. In this manner it is not only possible to make the personal computer according to the invention available at very low costs, but also to completely optimize the design of the personal computer according to the invention towards minimal heat generation, compact construction, and to make it less prone to failure. For the external power supply a simple and inexpensive standard power supply can be used.

In still another aspect of the invention, the personal computer according to the invention is characterized in that the input and output connections are designed for wireless use. Here also, connection possibilities that are in general hardly ever used, and that are only used because of so-called backward compatibility, may be dispensed with. Omitting the connection provisions for backward compatibility saves both space and electricity. With the provisions for wireless use, the personal computer according to the invention can be readily integrated in a wireless network so that the PC can be used completely independently while maintaining all the existing and future network facilities. The above elucidation of the invention as embodied in the appended claims is so clear and comprehensive that a person skilled in the art is able to understand it and, on the basis of the description, to use it.

Nonetheless, hereinafter the personal computer according to the invention will be further elucidated by way of and with reference to the drawing.

### BRIEF DESCRIPTION OF THE SEVERAL VIEWS OF THE DRAWINGS

The drawing shows in:

FIG. 1, an exploded oblique bottom view of the personal computer according to the invention; and in

FIG. 2, an exploded oblique top view of the personal computer shown in FIG. 1; and in

FIG. 3, a view of the personal computer with the connection provisions to be used.

### DETAILED DESCRIPTION OF THE INVENTION

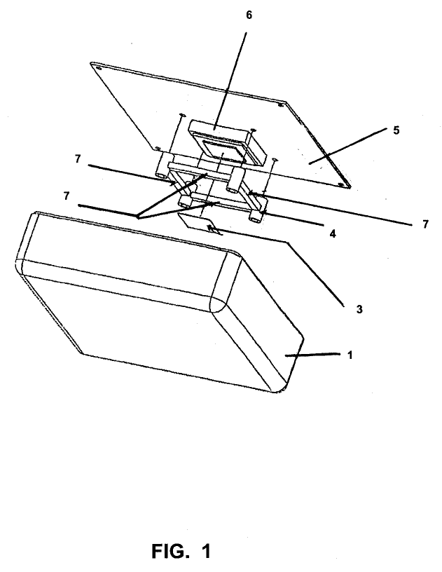

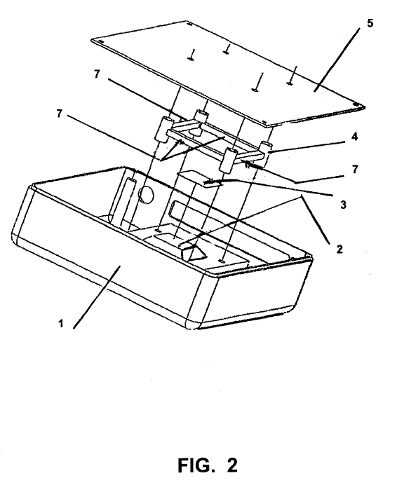

Referring to both FIG. 1 and FIG. 2, reference numeral 1 indicates a housing of the personal computer according to the invention with approximate dimensions of, for example, a width of 235 mm, a depth of 160 mm and a height of 80 mm. Variations on these dimensions are of course possible, and do not constitute a departure from the scope of the invention.

The housing 1 is embodied with a heat sink 2 forming an integral part with this housing 1; this is shown in FIG. 2.

The motherboard 5 should be mounted in the housing 1 in such a manner that the central processor unit 3 placed on the motherboard 5 is positioned closely against said heat sink 2 of the housing 1. This provides the desired stability.

The stability just mentioned can be furthered by using a frame 4 for mounting the motherboard 5, while this is provided with the central processor unit 3, on the heat sink 2. When this mounting is completed, the central processor unit 3 is positioned between the motherboard 5, the heat sink 2 and the legs 7 of the frame 4 surrounding the central processor unit 3.

Further, it is conducive to the transfer of heat between the central processor unit 3 and the heat sink 2, if a contact paste is provided between these two. The use of such a contact paste is well known to the skilled person, so that there is no need to show this in the figure.

In a manner well known to the person skilled in the art, the personal computer according to the invention may further be provided with input and output connections for peripheral equipment such as VDU, keyboard and mouse.

These input and output connections are preferably designed for wireless use and there are no other input and output connections provided except those for general peripheral equipment applications with DSB, 1394 (firewire) and LAN.

In addition, there is preferably also a connection for an external power supply so that there is no need of a power supply unit inside the housing 1.

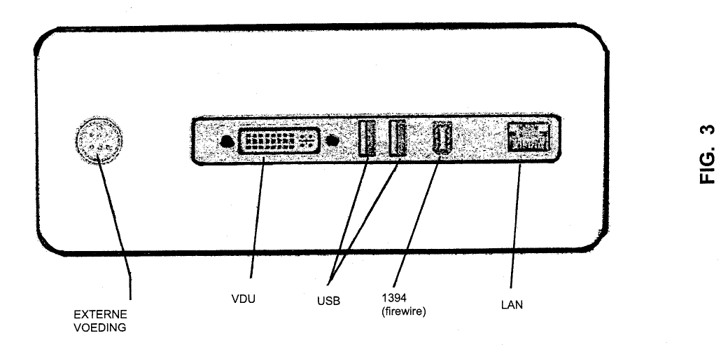

FIG. 3 shows a preferred configuration of the connections to be used in an otherwise wireless embodiment, with:
a LAN connection, for example, for a wireless network or an Internet connection.
USB for keyboard or mouse.
VDU for a display screen.
1394 or firewire bus for general peripheral equipment connections.

In the established manner, the capacity of the heat sink 2 should be geared to the expected heat generation of the central processor unit 3. The housing 1 is then embodied without fan and without accessory fan drive.

What is claimed is:

1. A personal computer comprising a housing, and placed in the housing a motherboard that is at least provided with one central processor unit, which computer is provided with input and output connections for peripheral equipment such as VDU, keyboard and mouse, and which is provided with a heat sink whose capacity is geared to the heat generation of the central processor unit, wherein the housing is coupled with the heat sink, and is embodied without fan and without an accessory fan drive, and wherein the heat sink is an integral part of the housing and the motherboard is mounted in the housing in such a manner that the central processor unit is stably positioned against the heat sink.

2. A personal computer according to claim 1, wherein the motherboard, while the same is provided with the central processor unit, is mounted on the heat sink using a frame in such a manner that the central processor unit is positioned between the motherboard, the heat sink and the frame's legs surrounding the central processor unit.

3. A personal computer according to claim 1, wherein a contact paste is applied between the heat sink and the central processor unit.

4. A personal computer according to claim 1, wherein the central processor unit is of the kind that has an electricity saving function, and that the electricity saving function is at least partly deactivated.

5. A personal computer according to claim 1, wherein the input and output connections and the respective software interfaces are limited to general peripheral equipment applications with USB, 1394 (firewire) and LAN.

6. A personal computer according to claim 1, wherein the housing has no ventilation openings.

7. A personal computer according to claim 1, wherein a connection for an external power supply is provided and there is no power supply unit inside the housing.

8. A personal computer according to claim 1, wherein the input and output connections are designed for wireless use.
